(19) United States
(12) Patent Application Publication
(10) Pub. No.: US 2026/0047436 A1
(43) Pub. Date: Feb. 12, 2026

(54) COOLING SYSTEM FOR COMPUTER SYSTEM COMPONENTS AND METHDS OF OPERATING THE SAME

(71) Applicant: Taiwan Semiconductor Manufacturing Company, Ltd., Hsinchu (TW)

(72) Inventors: Chung-Chiu WU, Hsinchu (TW); Wei-Sheng LIN, Hsinchu (TW)

(73) Assignee: Taiwan Semiconductor Manufacturing Company, Ltd., Hsinchu (TW)

(21) Appl. No.: 18/799,482

(22) Filed: Aug. 9, 2024

(51) Int. Cl. H01L 23/44; H01L 23/02; H01L 23/31; H01L 23/373; H03H 9/17

(52) U.S. Cl. CPC H01L 23/44; H01L 23/02; H01L 23/3107; H01L 23/373; H03H 9/17

(57) ABSTRACT

A method of cooling a semiconductor package module is provided. The method includes operating a semiconductor package module immersed in a liquid coolant in a tank. The method includes applying a driving voltage to a piezoelectric element or ultrasonic vibrating element disposed on the semiconductor package module to generate a vibration. The method further includes repelling bubbles of the liquid coolant formed on a surface of the semiconductor package module by way of the vibration.

### BACKGROUND

Cooling systems are used to maintain optimal temperatures in computer systems, especially for high-performance computing packages including central processing units (CPUs), graphics processing units (GPUs), and accelerated processing units (APUs) that generate considerable heat during operation. There are several types of cooling solutions, including air cooling, liquid or immersion cooling, and phase-change cooling. Each has its own advantages and is suited for different scenarios depending on factors including performance requirements, space constraints, and budget. Liquid or immersion cooling systems are increasingly being adopted in high-performance computing environments where conventional air cooling may fall short in dissipating the heat generated by components such as integrated circuit (IC) packages, high bandwidth memory (HBM), CPUs, APUs, and GPUs. One key advantage of liquid cooling lies in its efficiency at transferring heat away from heat sources. In contrast to air, liquid has a higher heat capacity, enabling it to absorb more heat before reaching critical temperatures. Despite advances in liquid cooling systems, challenges remain and there is an ongoing need for improvement in cooling or immersion systems for computer components and data systems to prevent malfunction of the components resulting from overheating.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic plane view illustrating an electronic system in accordance with some embodiments of the disclosure.

FIG. 2 is a schematic three-dimensional side-view illustrating a plurality of electronic systems being placed in an immersion cooling apparatus in accordance with some embodiments of the disclosure.

FIG. 3A is an exploded view of a semiconductor package module in accordance with some embodiments of the disclosure.

FIG. 3B is a top view of an assembled semiconductor package module before being fixed to a printed circuit board (PCB) in accordance with some embodiments of the disclosure.

FIGS. 4A-4B are cross-sectional views of semiconductor package modules along line A-A′ of FIG. 1 in accordance with some embodiments of the disclosure.

FIG. 5 is a schematic view of a ceramic piezoelectric element in accordance with some embodiments of the disclosure.

FIGS. 6A, 6B, 6C, and 6D are cross-sectional views of semiconductor package modules along line A-A′ of FIG. 1 in accordance with other embodiments of the disclosure.

FIG. 7A is a cross-sectional view of a semiconductor package module along line A-A′ of FIG. 1 in accordance with other embodiments of the disclosure.

FIG. 7B is a top view of a semiconductor package module disposed in an immersion cooling tank in accordance with embodiments of the disclosure.

FIG. 8 is a cross-sectional view of a semiconductor package module along line A-A′ of FIG. 1 in accordance with other embodiments of the disclosure.

FIG. 9 is a flowchart illustrating operations of a method of cooling a computing device, according to various embodiments.

FIG. 10 is a flowchart illustrating operations of a method of cooling a computing device, according to various embodiments.

### DETAILED DESCRIPTION

The following disclosure provides many different embodiments, or examples, for implementing various features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Disclosed embodiments provide cooling systems for computer system components having advantages over existing cooling systems. Embodiments include enhanced heat dissipation capability of a boiler plate used in an immersion or liquid cooling environment. In certain embodiments, a piezoelectric element or ultrasonic vibrating element is provided on or near a boiler plate to repel bubbles from the boiler plate and increase heat dissipation performance of the boiler plate. With enhanced heat dissipation performance an increase of computing density (e.g., total computing power) of servers is achieved. Moreover, in certain embodiments, higher heat flux components such as CPUs, APUs, and GPUs can operate at higher thermal design power (TDP). TDP for CPUs, APUs, and GPUs refers to the maximum amount of heat the unit can generate under a sustained workload. Thus, with a higher TDP, the GPUs, APUs, and CPUs can handle more demanding tasks while consuming more power and generating more heat.

Liquid or immersion cooling is increasingly being adopted in computer servers, particularly in data centers and high-performance computing (HPC) environments. The terms liquid cooling and immersion cooling are used interchangeably throughout the present disclosure. While air cooling has traditionally been the dominant method for cooling servers due to its simplicity and lower initial costs, liquid cooling offers several advantages that make it appealing for certain server deployments. In data centers, where energy efficiency and cooling capacity are important concerns, liquid cooling may offer significant benefits. Liquid cooling systems may more effectively remove heat from server components, enabling higher-density deployments without risking overheating. This allows data center operators to maximize their server density within the same footprint, reducing the overall space requirements and potentially lowering operational costs.

Liquid cooling also enables more efficient cooling of high-power components, such as CPUs, GPUs, APUs, and memory modules, which are increasingly common in modern server architectures. By keeping these components at optimal operating temperatures, liquid cooling may improve performance and reliability, leading to better overall server efficiency. Moreover, liquid cooling may contribute to energy savings in data centers by reducing the need for mechanical cooling systems, such as air conditioning units. By leveraging liquid cooling solutions that utilize ambient or recycled coolant, data centers may achieve significant reductions in power consumption and cooling costs. As the demand for higher computing densities, energy efficiency, and performance continues to rise, liquid cooling is likely to become increasingly prevalent in server deployments, especially in specialized HPC and hyperscale data center environments.

Liquid cooling technology includes phase-change cooling and two-phase cooling systems. Phase-change cooling and two-phase cooling share the fundamental principle of utilizing phase transitions to achieve cooling, but they differ in their implementation and operation. Phase-change cooling systems employ a refrigerant that undergoes a phase change from liquid to gas and back again to efficiently transfer heat away from heat-generating components. This process involves a closed-loop system that includes a compressor, condenser, expansion valve, and evaporator. The compressor compresses the refrigerant into a high-pressure liquid, which then passes through the condenser to release heat and condenses the refrigerant into a liquid. After passing through an expansion valve, the refrigerant evaporates into a low-pressure gas, absorbing heat from the component that is being cooled. This gas is then cycled back to the compressor to repeat the process.

In contrast, two-phase cooling encompasses a broader category of cooling techniques where both liquid and vapor phases of the coolant coexist simultaneously. In these systems, the coolant partially vaporizes as it absorbs heat from the component, and the resulting mixture of liquid and vapor interacts with a heat exchanger (i.e., a condenser) where the vapor condenses back into liquid, releasing the absorbed heat. This condensed liquid then returns to the component to continue the cooling cycle. Thus, while phase-change cooling is a specific type of cooling system involving phase changes between liquid and gas states, two-phase cooling encompasses a wider range of techniques utilizing both liquid and vapor phases of the coolant concurrently.

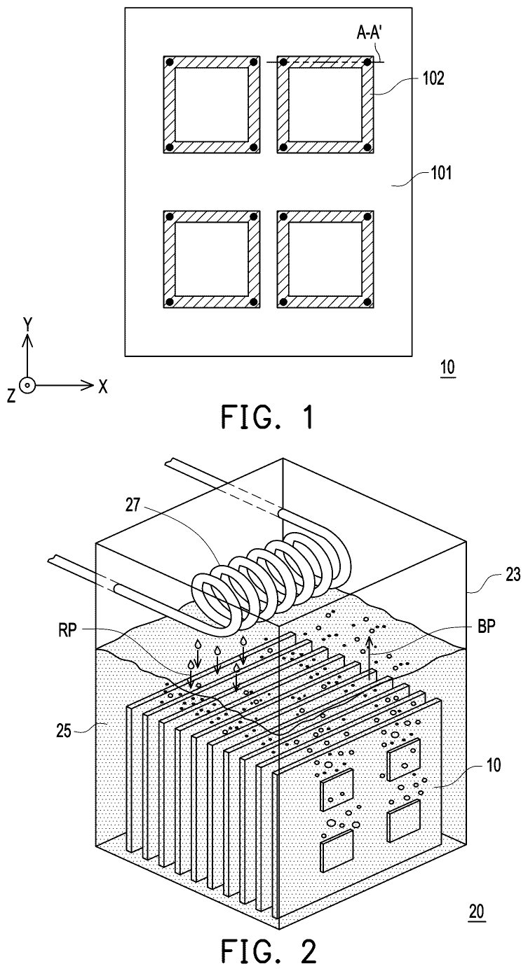

FIG. 1 is a schematic plan view illustrating an electronic system 10 in accordance with some embodiments of the disclosure. FIG. 2 is a schematic three-dimensional side-view illustrating a plurality of the electronic systems 10 depicted in FIG. 1 being placed in an immersion cooling apparatus 20 in accordance with some embodiments of the disclosure. In some embodiments, the electronic system 10 includes a printed circuit board 101 and one or more than one semiconductor package module 102. The one or more than one semiconductor package module 102 may include a plurality of semiconductor package modules 102, as shown in FIG. 1. For example, the semiconductor package modules 102 are attached and electrically coupled to the printed circuit board 101. The semiconductor package modules 102 are electrically coupled to and electrically communicated to each other through the printed circuit board 101. Although not shown, the printed circuit board 101 may be further attached with and electrically coupled with other electronic component(s) which may or may not be electrically coupled to at least some of the semiconductor package modules 102. In some embodiments, the electronic system 10 is a data server. In certain embodiments, each semiconductor package module 102 in the electronic system 10 may include a processing die and one or more memory device(s).

Further, a number of the semiconductor package modules 102 included in the electronic system 10 can be varied. Although four semiconductor package modules 102 are shown in the electronic system 10 in FIG. 1 for illustrative purposes, the number of the semiconductor package modules 102 included in one electronic system 10 can be less than or more than four; the disclosure is not limited thereto. The number of the semiconductor package modules 102 included in one electronic system 10 can be selected and designated, based on the demand and design requirements.

In some alternative embodiments, an additional printed circuit board may be adopted and interposed between one semiconductor package module 102 and the printed circuit board 101 to provide further routing functions. The additional printed circuit board is electrically coupled to and electrically communicates with the semiconductor package module 102 and the printed circuit board 101. In the plan view of FIG. 1, an occupying area of the additional printed circuit board may be less than or substantially equal to an occupying area of the printed circuit board 101, and may be greater than or substantially equal to an occupying area of the semiconductor package module 102.

Referring to FIG. 1 and FIG. 2 together, in some embodiments, the immersion cooling apparatus 20 includes a tank 23, a dielectric coolant 25, and a condenser 27, where multiple electronic systems 10 are accommodated in the tank 23 and immersed in the dielectric coolant 25. Although not shown, the electronic systems 10 may be respectively inserted into a slot at a bottom surface of the tank 23, such that the electronic systems 10 may stand in parallel with one another in the tank 23 and fixed to a bottom surface of the tank 23. In some embodiments, the tank 23 is filled with the dielectric coolant 25. The electronic systems 10 may be submerged in a bath of the dielectric coolant 25, and thermal energy generated by the electronic systems 10 can be dissipated through the dielectric coolant 25. Since the dielectric coolant 25 is not electrically conductive, shorting between the electronic systems 10 may be avoided.

In some embodiments, the immersion cooling apparatus 20 is a two-phase immersion cooling apparatus. In these embodiments, the dielectric coolant 25 (e.g., a dielectric cooling liquid) has a low boiling point (e.g., about 50° C.), and the dielectric coolant 25 boils on surfaces of heat-generating components (e.g., boiler plate 107) by which a liquid phase turns into a gas phase (e.g., a vapor). The rising vapor (e.g., indicated by a bubble path BP in FIG. 2) transfers heat out of the dielectric coolant 25, thus heat can be removed from the electronic systems 10. In some embodiments, the condenser 27 (e.g., a coil condenser) is disposed over the bath of the dielectric coolant 25 inside the tank 23, and the vapor (e.g. the gas phase of the dielectric coolant 25) is cooled at the condenser 27, then returns to the bath of the dielectric coolant 25 (by which the gas phase returns into the liquid phase (e.g. indicated by a return path RP in FIG. 2)).

In certain embodiments, the dielectric coolant 25 is a fluorine-based chemical having a boiling point between 46° C. and 55° C., a latent heat between 90 kJ/kg and 125 kJ/kg, and a vapor pressure between 30 kPa and 40 kPa at temperature of approximately 20° C. Some example chemicals that may be used as the dielectric coolant 24 include: HT-55 ((perfluoropolyether) (1-propene, 1,1,2,3,3,3-hexafluoro-, oxidized, polymerized)) available from Galden; Novec 7200 (ethyl nonafluoroisobutyl ether) available from 3M; FC16P (1,1,1,2,2,4,5,5,5-nonafluoro-4-(trifluoromethyl)-3-pentanone) available from Taimax; Novec 649 (1,1,1,2,2,4,5,5,5-nonafluoro-4-(trifluoromethyl)-3-pentanone) available from 3M; FC-3284 (perfluoro compounds, C5-18) available from 3M; FC18P (2-pentene, 1,1,1,2,3,4,5,5,5-nonafluoro-4-(trifluoromethyl)) available from Taimax; IM6 (perfluoro(4-methylpent-2-ene)) available from Inventec; 2100A (perfluoro(4-methylpent-2-ene)) available from Noah; DAISAVE SS-54 (1,1,2,3,3,3-hexafluoropropyl methyl ether) available from Daikin; and Opteon 2P50 (hydrofluoroolefin) available from Chemours.

The electronic systems 10 are not limited to the immersion cooling apparatus 20 as shown in FIG. 2. A suitable cooling apparatus for the electronic systems 10 may be adopted, as long as the heat generated from the electronic systems 10 can be effectively removed. In addition to the external heat dissipation path, a heat dissipation path in each electronic system 10 significantly affects the heat dissipation efficiency of the electronic system 10.

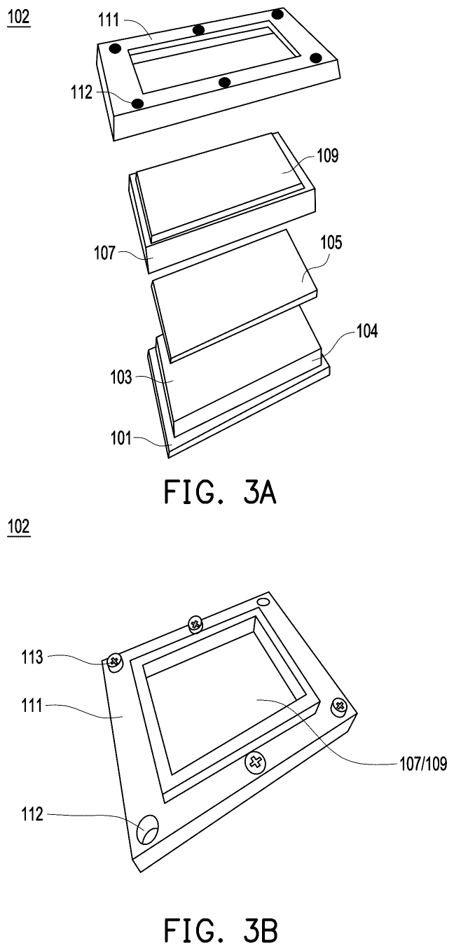

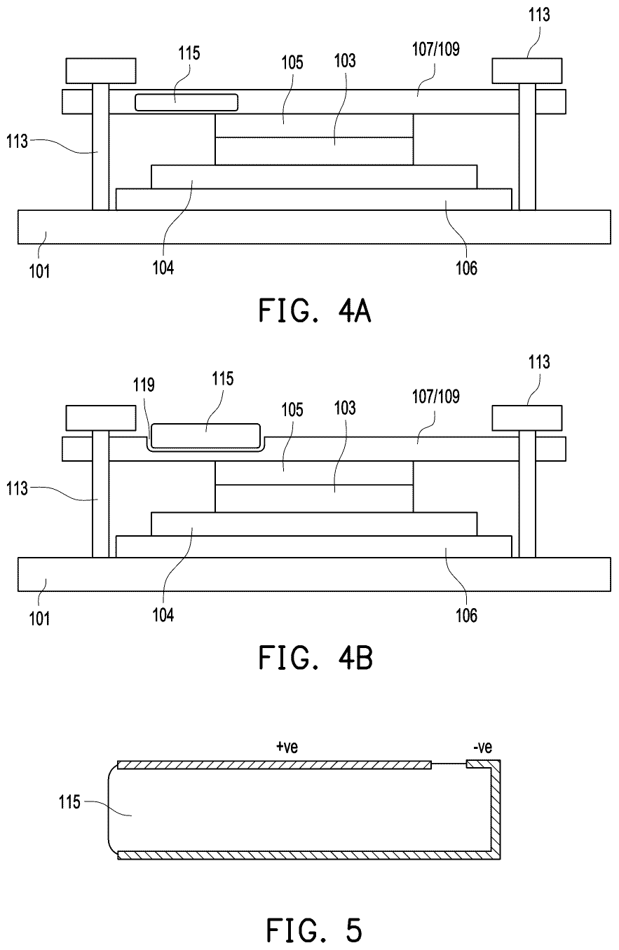

FIG. 3A is an example of an exploded view of a semiconductor package module 102 and FIG. 3B is an example of an assembled semiconductor package module 102. In some embodiments, the semiconductor package modules 102 include a printed circuit board (PCB) 101. In some embodiments, a land grid array (LGA) 106 is disposed between the PCB 101 and substrate 104 (FIGS. 4A-4B). The LGA 106 is electronic packaging configured to permit mounting microprocessors or integrated circuits onto a PCB 101. In certain embodiments, the LGA 106 includes contacts or pins (not shown) arranged in a grid-like pattern. LGA 106 includes flat surfaces with pads and the pads can either connect to an LGA socket or are soldered directly to the PCB 101. In other embodiments, a ball grid array (BGA) or pin grid array (PGA) can be used instead of the LGA.

In some embodiments, the substrate 104 is made of a semiconductor material such as silicon, germanium, diamond, or the like. In other embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In some alternative embodiments, the substrate 104 is a silicon-on-insulator (SOI) substrate.

It is appreciated that, in some embodiments, the semiconductor die 103 described herein may be referred to as a semiconductor chip or an integrated circuit (IC). In some embodiments, the semiconductor die 103 is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor die 103 may include a digital chip, an analog chip, or a mixed signal chip. The semiconductor die 103 may be a chip or an IC of combination type, such as a WiFi chip simultaneously including both an RF chip and a digital chip.

In alternative embodiments, the semiconductor die 103 is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc. ; a combination thereof; or the like. In other alternative embodiments, the semiconductor die 103 is an electrical and/or optical input/output (I/O) interface die, an integrated passives die (IPD), a voltage regulator die (VR), a local silicon interconnect die (LSI) with or without deep trench capacitor (DTC) features, a local silicon interconnect die with multi-tier functions such as electrical and/or optical network circuit interfaces, IPD, VR, DTC, or the like. The type of the semiconductor die 103 may be selected and designated based on the demand and design requirement, and thus is not specifically limited in the disclosure.

In certain embodiments, a thermal interface material (TIM) 105 is disposed between the boiler plate 107 and the semiconductor die 103. The TIM 105 enhances the thermal coupling between the boiler plate 107 (e.g., a heat-dissipating plate, cover, or lid) and the semiconductor die 103 (e.g., a heat-producing device). In some embodiments, the TIM 105 includes a thermal paste, gels, grease, adhesive tape, or conductive pad. In some embodiments, the thermal tapes include pressure-sensitive adhesives (PSAs) coated on a support material such as polyimide film, fiberglass, aluminum foil, or mat. In other embodiments, the TIM 105 includes an adhesive material having good thermal conductivity. The adhesive includes any suitable adhesive, epoxy, die attach film (DAF), or the like and the adhesive may be deposited between the boiler plate 107 and the semiconductor die 103. In other embodiments, the TIM 105 includes graphite or graphene.

The boiler plate 107 is mounted on high heat flux devices such as CPUs, APUs, and GPUs to conduct heat to a boiling enhancement coating (BEC) 109 which is applied to a surface of the boiler plate 107 (FIG. 3A). In some embodiments, the boiler plate 107 includes materials such as metals or ceramics. In some embodiments, the boiler plate includes copper. The term copper includes substantially pure elemental copper, copper-containing unavoidable impurities, and copper alloys containing minor amounts of elements such as tantalum, indium, tin, zinc, manganese, chromium, titanium, germanium, strontium, platinum, magnesium, aluminum or zirconium, etc.

In certain embodiments, the BEC 109 is a metallic material optimized to initiate and enhance boiling of the dielectric coolant 25 and rapidly replenish liquid to the boiling surface. In some embodiments, the BEC 109 includes a copper mesh or copper powder structure applied to a surface of the boiler plate. The boiler plate 107 minimizes the temperature differential between the semiconductor die 103 and the dielectric coolant 25, enabling cooler operating temperatures and higher processing speeds.

In certain embodiments, the supporting structure 111 is fixed to the PCB 101 by way of fasteners 113 inserted through openings 112 (FIGS. 3A-3B). The supporting structure 111 surrounds the boiler plate 107 and BEC 109. In certain embodiments, the fasteners 113 include screws or secure posts. The supporting structure 111 may be thermally coupled to, electrically coupled to, or thermally and electrically coupled to the PCB 101. Owing to the supporting structure 111, the warpage control of the semiconductor package module 102 is enhanced. In addition, the heat may further be transferred to the supporting structure 111 for dissipating.

In certain embodiments, the supporting structure 111 may be referred to as a ring structure. The supporting structure 111 has a closed, full-frame shape of a rectangular annulus for illustrative purposes, however, the disclosure is not limited thereto. Alternatively, the supporting structure 111 may have a closed, continuous frame shape of a circular annulus, elliptical annulus, or other suitable polygonal annulus in plan view. Alternatively, the supporting structure 111 may have a discontinuous frame shape (e.g., with slits/openings) of the rectangular annulus, circular annulus, elliptical annulus, or other suitable polygonal annulus in plan view. In some embodiments, a material of the supporting structure 111 includes an electrically conductive material, a thermally conductive material, or an electrically and thermally conductive material. For example, the material of the supporting structure 111 includes metals or metal alloys, such as copper, aluminum, cobalt, copper coated with nickel, stainless steel, tungsten, copper-tungsten, copper-molybdenum, silver diamond, copper diamond, aluminum nitride, aluminum silicon carbide, or their alloys, stacking of different material combinations thereof, or the like. In certain embodiments, the supporting structure 111 is made of a material having high thermal conductivity between about 200 W/(m·K) to about 400 W/(m·K) or more. In the embodiments of which the supporting structure 111 has high thermal conductivity, the heat dissipation of the semiconductor package module 103 is further enhanced.

Embodiments of the present disclosure include integrating or adhering a piezoelectric element or ultrasonic vibrating element in the semiconductor package module 102 to enhance bubble dissipation from a surface of the boiler plate 107 or a surface of the BEC applied to a surface of the boiler plate 107. The piezoelectric element or ultrasonic vibrating element in accordance with certain embodiments permits bubbles to escape more efficiently from the boiler plate 107. At the contact surfaces of the dielectric coolant 25 and the boiler plate 107, bubbles often form as the dielectric coolant 25 undergoes a phase change from a liquid to a gas/vapor state. The piezoelectric element or ultrasonic vibrating element 115 provides ultrasonic energy to enhance bubble release from the surface of the boiler plate 107. With bubbles escaping at a faster rate from a surface of the boiler plate 107, an increase in the overall heat transfer coefficient is achieved.

FIGS. 4A and 4B are cross-sectional views of semiconductor package modules 102 in accordance with embodiments of the present disclosure. The cross-sectional view is taken along line A-A′ (FIG. 1). As shown in FIGS. 4A and 4B, one or more piezoelectric elements or ultrasonic vibrating elements 115 are integrated on or into the boiler plate 107. In the embodiment of FIG. 4A, a piezoelectric ceramic is integrated inside the boiler plate 107. In some examples, co-firing of the material for the boiler plate and the piezoelectric ceramic includes simultaneously sintering or firing the two different materials. In certain embodiments, the material for the boiler plate is copper, and a ceramic material such as lead zirconate titanate (PZT), lead magnesium niobate-lead titanate (PMN-PT), lithium niobate, or barium titanate is used for the piezoelectric element or ultrasonic vibrating element 115. The co-firing involves combining the two different materials during the firing or sintering process at about 1200° C. to create a layered composite.

In FIG. 4B, an example of installing or attaching a piezoelectric element or ultrasonic vibrating element 115 to the boiler plate is shown. In certain embodiments, the piezoelectric element or ultrasonic vibrating element 115 is directly adhered to a surface of the boiler plate 107 or a surface of the BEC 109 disposed over the boiler plate 107. In certain embodiments, one or more openings 119 are cut or etched out of a surface of the boiler plate and the piezoelectric element or ultrasonic vibrating element 115 is fixed or adhered to the boiler plate 107 in the opening. The piezoelectric element or ultrasonic vibrating element 115 can be fixed to a surface of the boiler plate 107 by way of an adhesive such as an epoxy adhesive (not shown). In alternative embodiments, other types of ultrasound sources are used in place of the piezoelectric ceramic element. The ultrasound sources in certain embodiments are encapsulated and packaged as a transducer. In certain embodiments, the transducer is laminated and installed or fixedly secured on or near the boiler plate 107 to provide a reliable source of ultrasonic waves sufficient to repel bubbles from the surface of the boiler plate 107. In the examples of FIGS. 4A and 4B, the BEC 109 (not shown) is applied to an outer surface of the boiler plate as discussed above.

In FIG. 5, an example of a piezoelectric element 115 is shown. In certain embodiments, the electrodes +ve and −ve are wrapped around the piezoelectric ceramic. In the example of FIG. 5, the wrapped electrodes are designed to be on the same side of the piezoelectric element to facilitate access and attachment to driving voltage signals. In certain embodiments, by utilizing a piezoelectric effect, piezoelectric ceramics extend and shrink (vibrate) depending on the frequency of the voltage that is applied. This vibration generates ultrasound or high-frequency sound waves to repel or displace bubbles from a surface of the boiler plate 107 and improve heat dissipation capability of the boiler plate in a liquid or immersion cooling environment. In certain embodiments, ultrasound waves are delivered at a frequency of about 40 kHz to 5 MHz.

In some embodiments, the piezoelectric ceramic, piezoelectric transducer, or ultrasonic transducer are actively controlled and configured to have a utilization rate (or operating state) adjusted based on the CPU, GPU, or APU loading levels and/or vapor conditions. In certain embodiments, if the CPU, GPU, or APU loading levels (e.g., high TDP) are operating at higher levels then the operating state of the piezoelectric ceramic, piezoelectric transducer, or ultrasonic transducer is increased. Moreover, if an excessive amount of vapor occurs on a surface of the boiler plate, the operating state of the piezoelectric ceramic, piezoelectric transducer, or ultrasonic transducer can be actively increased. Non-limiting examples of the electrical properties of the ultrasonic waves that are adjustable include magnitude, frequency, and waveform shape.

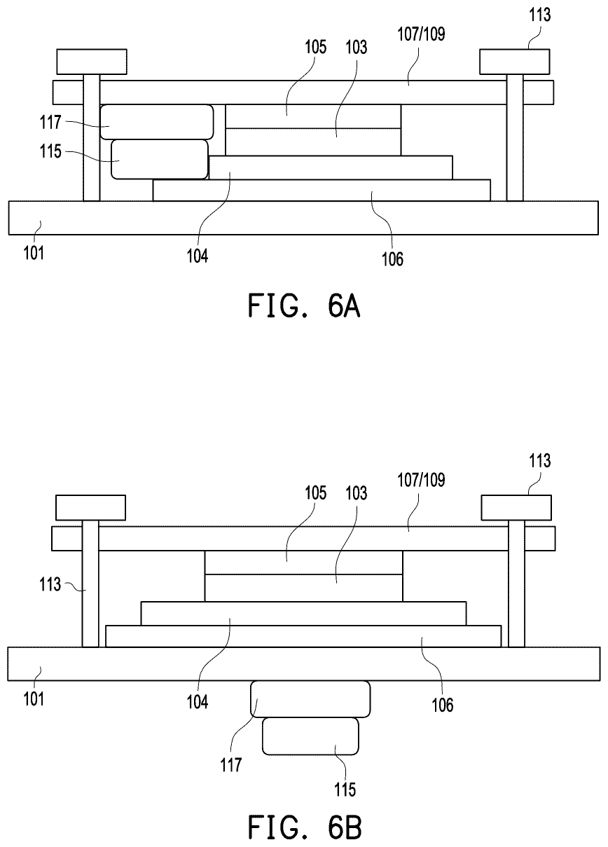

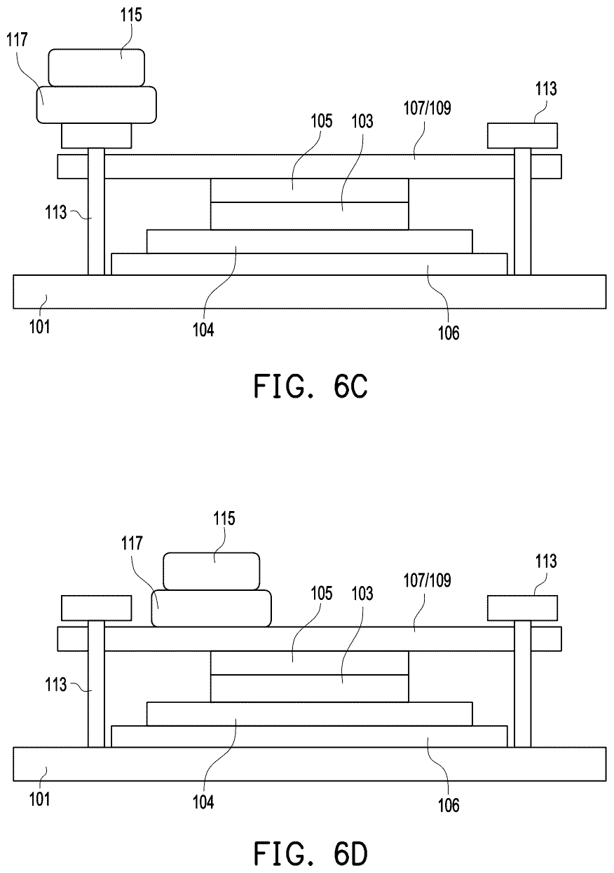

In other embodiments, the location of the piezoelectric element or ultrasonic vibrating element 115 is varied. In some embodiments, the piezoelectric element or ultrasonic vibrating element 115 are positioned on a front-facing surface of the boiler plate 107 (e.g., FIG. 4B). In other embodiments, the piezoelectric element or ultrasonic vibrating element 115 is located on an inner surface or inside of the boiler plate 107, as shown in FIG. 6A. In certain embodiments, the piezoelectric element or ultrasonic vibrating element 115 is located on an outer surface or outside of the boiler plate 107, as shown in FIG. 6D. The location of the piezoelectric element or ultrasonic vibrating element 115 can vary as long as the ultrasonic waves can propagate via the boiler plate and reach a front surface of the boiler plate 107 to repel the bubbles. In other embodiments, as shown in FIG. 6B, the piezoelectric element or ultrasonic vibrating element 115 is disposed on a surface of the PCB 101. In yet other embodiments, as shown in FIG. 6C, the piezoelectric element or ultrasonic vibrating element 115 is disposed on a surface of one or more of the fasteners 113.

In the embodiments shown in FIGS. 6A-6D, an acoustic medium 117 is disposed between a surface of the boiler plate and the piezoelectric element or ultrasonic vibrating element 115. The acoustic medium 117 provides acoustic impedance matching between the piezoelectric element or ultrasonic vibrating element 115 and the boiler plate 107 to enhance the performance of the piezoelectric element or ultrasonic vibrating element 115. In certain embodiments, the acoustic medium 117 couples waves between the piezoelectric element or ultrasonic vibrating element 115 and the boiler plate 107. The wave coupling is necessary due to a difference in the materials of the piezoelectric element or ultrasonic vibrating element 115 and the boiler plate 107 which leads to a mismatch in the acoustic properties. The mismatch leads to the reverberation of waves within the piezoelectric element or ultrasonic vibrating element 115, heating, low signal-to-noise ratio, and signal distortion. Acoustic impedance matching by the acoustic medium 117 increases the coupling between the piezoelectric element or ultrasonic vibrating element 115 and the boiler plate 107. In certain embodiments, a gel or hydrogel material is used as an acoustic medium 117. In other embodiments, a nanocomposite material or polymer material is used as the acoustic medium 117.

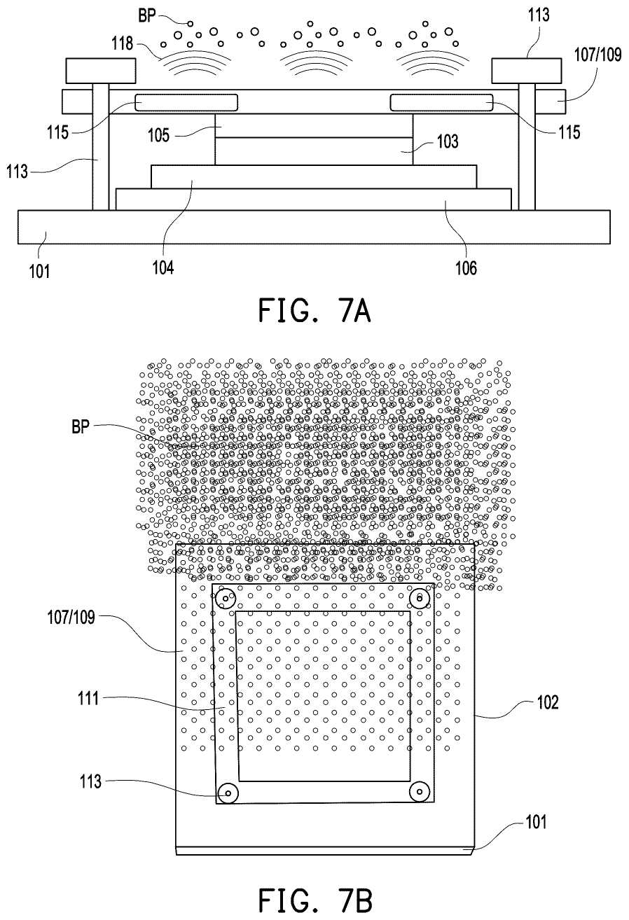

In other embodiments, a plurality of piezoelectric elements or ultrasonic vibrating elements 115 are included in the boiler plate 107, as shown in FIG. 7A. An increased rate of the escaping bubbles BP is obtained with the inclusion of piezoelectric element(s) or ultrasonic vibrating element(s) which are configured to generate ultrasonic waves 118. The repelling of the bubbles from the surface of the boiler plate 107 (or a surface of the BEC 109 applied over the boiler plate 107) results in improved heat transfer and thermal performance of the semiconductor package module 102. As shown in FIG. 7B, when the semiconductor package module 102 is installed in the tank 23 (FIG. 2) a greater percentage of bubbles BP are shown repelled above the semiconductor package module 102 than on a surface of boiler plate 107. As a result of the higher frequency vibration of the ultrasonic waves 118, the bubbles escape easier from the surface of the boiler plate 107. In the example of FIG. 7B, the semiconductor package module 102 is oriented in a tank 23 of the immersion cooling apparatus similar to what is illustrated in FIG. 2.

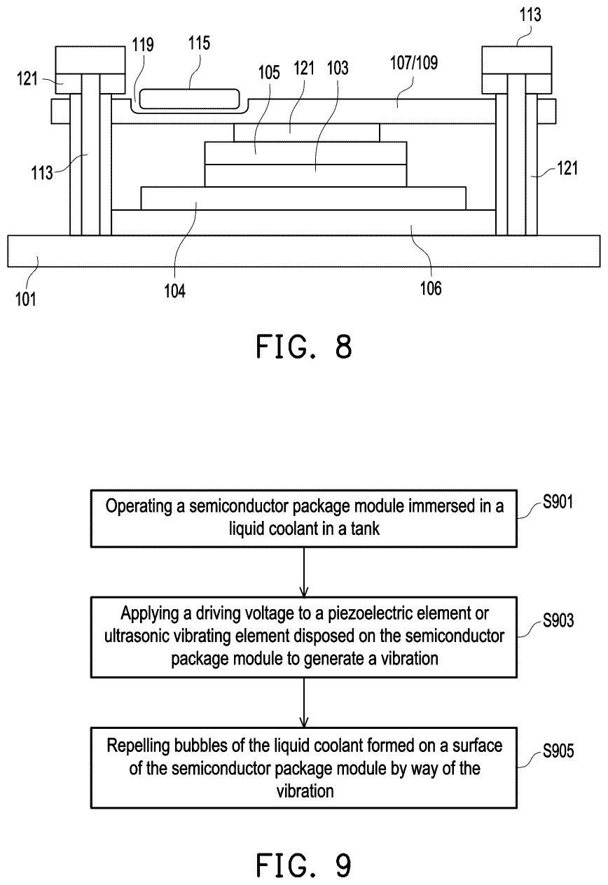

In certain embodiments, as shown in FIG. 8, a piezoelectric element or ultrasonic vibrating element 115 is installed or attached to an outer surface of the boiler plate 107. The piezoelectric element or ultrasonic vibrating element 115 is adhered to a surface of the boiler plate 107. As shown in FIG. 8, an opening 119 is cut or etched out of a surface of the boiler plate 107 and the piezoelectric element or ultrasonic vibrating element 115 is fixed or adhered to the boiler plate 107. In some embodiments, an insulating material 121 is applied to a plurality surfaces of the fasteners 113 and a portion of the inner surface of the boiler plate 107. In some embodiments, the insulating material includes a resin that prevents the driving voltage signals to the piezoelectric element or ultrasonic vibrating element 115 from leaking or reaching other components of the semiconductor package module 102. In certain embodiments, the insulating material 121 acts as an electrical insulator or blocker. Examples of insulating materials include synthetic phenolic resins including novolaks. Other examples include a phenol formaldehyde (PF) resin commercially sold under the name Bakelite®.

FIG. 9 is a flowchart illustrating operations of a method of cooling a semiconductor package module 102. The method includes operating a semiconductor package module immersed in a liquid coolant in a tank (S901). The method further includes applying a driving voltage to a piezoelectric element or ultrasonic vibrating element disposed on the semiconductor package module to generate a vibration (S903). The method includes repelling bubbles of the liquid coolant formed on a surface of the semiconductor package module by way of the vibration (S905).

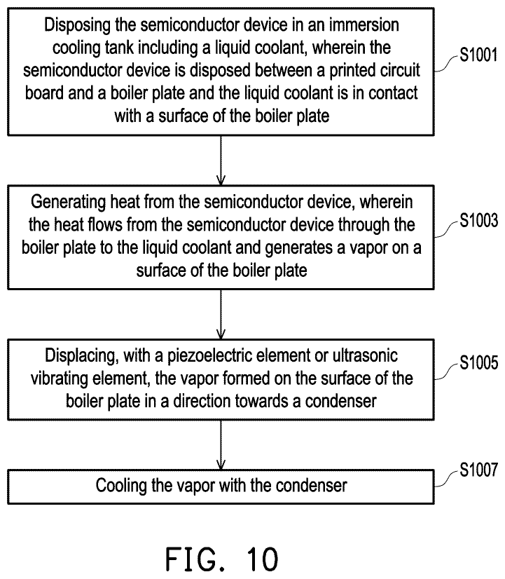

FIG. 10 is a flowchart illustrating operations of a further method of cooling a semiconductor device. The method includes disposing the semiconductor device in an immersion cooling tank, wherein the semiconductor device generates heat and is enclosed between a printed circuit board and a boiler plate (S1001). The method includes placing a liquid coolant in the immersion cooling tank such that the liquid coolant is in contact with a surface of boiler plate and the liquid coolant receives heat from the boiler plate and thereby generates a vapor on a surface of the boiler plate (S1003). The method further includes cooling the vapor with a condenser (S1005). The method further includes displacing, with a piezoelectric element or ultrasonic vibrating element, the vapor formed on the surface of the boiler plate in a direction towards the condenser (S1007).

Embodiments of the present disclosure are directed to enhancing heat dissipation capability of a boiler plate during immersion cooling. With the present embodiments, a piezoelectric element or ultrasonic vibrating element is provided on or near a boiler plate to repel bubbles from the boiler plate and increase heat dissipation performance of the boiler plate. With enhanced heat dissipation performance an increase of computing density of servers is achieved and the risk of damage to the servers due to overheating can be reduced.

It will be understood that not all advantages have been necessarily discussed herein, no particular advantage is required for all embodiments or examples, and other embodiments or examples may offer different advantages.

An embodiment according to the present disclosure is a method of cooling a semiconductor package module. The method includes operating the semiconductor package module immersed in a liquid coolant in a tank. The method further includes applying a driving voltage to a piezoelectric element or ultrasonic vibrating element disposed on the semiconductor package module to generate a vibration. The method includes repelling bubbles of the liquid coolant formed on a surface of the semiconductor package module by way of the vibration. In some embodiments, the liquid coolant comprises a dielectric liquid coolant. In certain embodiments, the semiconductor package module includes a boiler plate, and the bubbles are repelled from a surface of the boiler plate by way of the vibration. In other embodiments, the method includes embedding the piezoelectric element in the boiler plate of the semiconductor package module. In certain embodiments, a boiling enhancement coating (BEC) is disposed over the surface of the boiler plate. In other embodiments, the method includes fixing the semiconductor package module to a bottom surface of the tank. In other embodiments, the piezoelectric element or ultrasonic vibrating element is disposed on one or more fasteners. In some embodiments, an acoustic material is disposed between at least one of the one or more fasteners and the piezoelectric element or ultrasonic vibrating element.

Another embodiment according to the present disclosure is a method of cooling a semiconductor device. The method includes disposing the semiconductor device in an immersion cooling tank including a liquid coolant. The semiconductor device is disposed between a printed circuit board and a boiler plate and the liquid coolant is in contact with a surface of the boiler plate. Heat is generated from the semiconductor device. The heat flows from the semiconductor device through the boiler plate to the liquid coolant and generates a vapor on the surface of the boiler plate. The method includes displacing, with a piezoelectric element or ultrasonic vibrating element, the vapor formed on the surface of the boiler plate in a direction towards a condenser. The vapor is cooled with the condenser. In some embodiments, the displacing step includes generating a voltage signal to the piezoelectric element or ultrasonic vibrating element to create a sound wave to displace the vapor. In other embodiments the liquid coolant comprises a dielectric coolant. In some embodiments, the piezoelectric element includes a piezoelectric ceramic disposed on or in the boiler plate. In certain embodiments, a support frame surrounds the boiler plate and is fixed to the printed circuit board by way of fasteners. With other embodiments, the piezoelectric element includes a piezoelectric transducer disposed on one or more of the fasteners.

In yet another embodiment, a semiconductor package module is provided. The semiconductor package module includes a semiconductor die. A thermal interface material (TIM) is disposed over the semiconductor die. A boiler plate is disposed over the TIM. The semiconductor package module includes a piezoelectric element or ultrasonic vibrating element. A supporting frame is disposed over the boiler plate. In some embodiments, a boiling enhancement coating (BEC) is applied to a surface of the boiler plate. In other embodiments, the piezoelectric element is disposed on or in the boiler plate. In some embodiments, the piezoelectric element includes a ceramic piezoelectric element. With other embodiments, the piezoelectric element is disposed on a portion of the supporting frame. In certain embodiments, an acoustic medium is disposed between the piezoelectric element and the boiler plate

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure and that they may make various changes, substitutions, and alterations herein without departing from the spirit and scope of the present disclosure.

What is claimed is:

1. A method of cooling a semiconductor package module, comprising:
operating the semiconductor package module immersed in a liquid coolant in a tank;
applying a driving voltage to a piezoelectric element or ultrasonic vibrating element disposed on the semiconductor package module to generate a vibration; and
repelling bubbles of the liquid coolant formed on a surface of the semiconductor package module by way of the vibration.

2. The method according to claim 1, wherein the liquid coolant comprises a dielectric liquid coolant.

3. The method according to claim 1, wherein the semiconductor package module includes a boiler plate, and the bubbles are repelled from a surface of the boiler plate by way of the vibration.

4. The method according to claim 3, further comprising:
embedding the piezoelectric element in the boiler plate of the semiconductor package module.

5. The method according to claim 3, wherein a boiling enhancement coating (BEC) is disposed over the surface of the boiler plate.

6. The method according to claim 1, further comprising:
fixing the semiconductor package module to a bottom surface of the tank.

7. The method according to claim 6, wherein the piezoelectric element or ultrasonic vibrating element is disposed on one or more fasteners.

8. The method according to claim 7, wherein an acoustic material is disposed between at least one of the one or more fasteners and the piezoelectric element or ultrasonic vibrating element.

9. A method of cooling a semiconductor device, comprising:
disposing the semiconductor device in an immersion cooling tank including a liquid coolant,
wherein the semiconductor device is disposed between a printed circuit board and a boiler plate and the liquid coolant is in contact with a surface of the boiler plate;
generating heat from the semiconductor device,
wherein the heat flows from the semiconductor device through the boiler plate to the liquid coolant and generates a vapor on the surface of the boiler plate;
displacing, with a piezoelectric element or ultrasonic vibrating element, the vapor formed on the surface of the boiler plate in a direction towards a condenser; and
cooling the vapor with the condenser.

10. The method according to claim 9, wherein the displacing includes generating a voltage signal to the piezoelectric element or ultrasonic vibrating element to create a sound wave to displace the vapor.

11. The method according to claim 9, wherein the liquid coolant comprises a dielectric coolant.

12. The method according to claim 9, wherein the piezoelectric element comprises a piezoelectric ceramic disposed on or in the boiler plate.

13. The method according to claim 9, wherein a support frame surrounds the boiler plate and is fixed to the printed circuit board by way of fasteners.

14. The method according to claim 13, wherein the piezoelectric element comprises a piezoelectric transducer disposed on one or more of the fasteners.

15. A semiconductor package module, comprising:
a semiconductor die;
a thermal interface material (TIM) disposed over the semiconductor die;
a boiler plate disposed over the TIM;
piezoelectric element or ultrasonic vibrating element; and
a supporting frame disposed over the boiler plate.

16. The semiconductor package module according to claim 15, further comprising:
a boiling enhancement coating (BEC) applied to a surface of the boiler plate.

17. The semiconductor package module according to claim 15, wherein the piezoelectric element is disposed on or in the boiler plate.

18. The semiconductor package module according to claim 17, wherein the piezoelectric element comprises a ceramic piezoelectric element.

19. The semiconductor package module according to claim 15, wherein the piezoelectric element is disposed on a portion of the supporting frame.

20. The semiconductor package module according to claim 15, further comprising an acoustic medium disposed between the piezoelectric element and the boiler plate.
